(19) United States
(12) Patent Application Publication
(10) Pub. No.: US 2025/0318155 A1
(43) Pub. Date: Oct. 9, 2025

(54) PACKAGE WITH PERMALLOY CORE INDUCTOR AND MANUFACTURING METHOD THEREOF

(71) Applicant: Taiwan Semiconductor Manufacturing Co., Ltd., Hsinchu (TW)

(72) Inventor: Wen-Shiang Liao, Toufen Township (TW)

(21) Appl. No.: 19/243,246

(22) Filed: Jun. 19, 2025

Related U.S. Application Data
(62) Division of application No. 17/844,476, filed on Jun. 20, 2022.

(51) Int. Cl. H10D 1/20; H01L 21/56; H01L 23/00; H01L 25/16

(52) U.S. Cl. CPC H10D 1/20; H01L 25/165; H01L 21/565; H01L 24/16; H01L 24/32; H01L 24/73; H01L 2224/16235; H01L 2224/32225; H01L 2224/73204; H01L 2924/182; H01L 2924/19042

(57) ABSTRACT

A package includes a first redistribution structure, a die disposed over the first redistribution structure, a molding material surrounding the die, a second redistribution structure over the die and the molding material, and an inductor includes a permalloy core. The permalloy core is embedded in the molding material, and the permalloy core includes vertically stacked alternating layers. The vertically stacked alternating layers includes epoxy layers, and permalloy layers, where each of the permalloy layers is disposed between two epoxy layers of the epoxy layers.

### CROSS-REFERENCE TO RELATED APPLICATIONS

This application is a divisional of U.S. application Ser. No. 17/844,476, filed on Jun. 20, 2022, which application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged. An example is the integration of inductors in such packaging systems. Inductors can be used for various applications, such as filters in circuits, energy storage components, reactors to depress voltage, switching current limiters or transformers.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of an integrated circuit die in accordance with some embodiments.

FIGS. 2 through 16B illustrate cross-sectional views, top-down views and a perspective view of intermediate steps during a process for forming a package component in accordance with some embodiments.

FIGS. 16C illustrates a perspective view of the package component in accordance with some embodiments.

FIG. 16D illustrates traces of inductance versus operating frequency for different types of inductors, in accordance with some embodiments.

FIG. 16E illustrates traces of resistance versus operating frequency for different types of inductors, in accordance with some embodiments.

FIGS. 17A and 17B illustrates a cross-sectional view and a top-down view of intermediate steps during a process for forming a package component in accordance with other embodiments.

FIG. 18 illustrates a top-down view of intermediate steps during a process for forming a package component in accordance with other embodiments.

FIG. 19 illustrates a top-down view of intermediate steps during a process for forming a package component in accordance with other embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide methods of forming an integrated circuit package that includes an inductor having a magnetic permalloy core. The permalloy core comprises a plurality of vertically stacked alternating layers that include a plurality of permalloy layers and a plurality of epoxy layers, such that each permalloy layer of the plurality of permalloy layers is disposed between two epoxy layers of the plurality of epoxy layers. The permalloy core may be a magnetic bar that is formed to be in the shape of a closed loop (e.g., having a toroidal loop shape, rectangular loop shape, or the like), or may comprise a plurality of closed loops. Advantageous features of one or more embodiments disclosed herein may include increased magnetic permeability of the permalloy core, which results in a higher inductance. The permalloy core comprising a plurality of closed loops also allows for a further inductance increase. Further, the disclosed method may provide more efficient and compact power inductors that can be integrated easily into existing processes and provide improved inductor performance with lower manufacturing costs and improve space utilization.

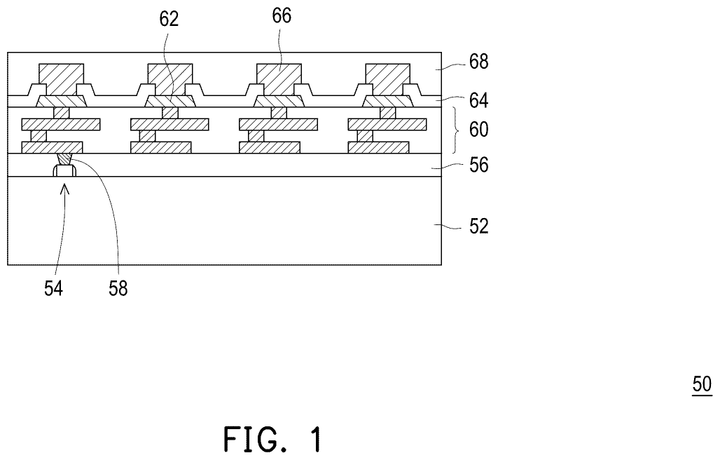

FIG. 1 illustrates a cross-sectional view of an integrated circuit die 50 in accordance with some embodiments. The integrated circuit die 50 will be packaged in subsequent processing to form an integrated circuit package. The integrated circuit die 50 may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), a high-performance computing (HPC) die, an artificial intelligence (AI) die, an automotive die, the like, or combinations thereof.

The integrated circuit die 50 may be formed in a wafer, which may include different device regions that are singulated in subsequent steps to form a plurality of integrated circuit dies. The integrated circuit die 50 may be processed according to applicable manufacturing processes to form integrated circuits. For example, the integrated circuit die 50 includes a semiconductor substrate 52, such as silicon, doped or undoped, or an active layer of a semiconductor-on-insulator (SOI) substrate. The semiconductor substrate 52 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 52 has an active surface (e.g., the surface facing upwards in FIG. 1), sometimes called a front side, and an inactive surface (e.g., the surface facing downwards in FIG. 1), sometimes called a back side.

Devices (represented by a transistor) 54 may be formed at the front surface of the semiconductor substrate 52. The devices 54 may be active devices (e.g., transistors, diodes, etc.), capacitors, resistors, etc. An inter-layer dielectric (ILD) 56 is over the front surface of the semiconductor substrate 52. The ILD 56 surrounds and may cover the devices 54. The ILD 56 may include one or more dielectric layers formed of materials such as Phospho-Silicate Glass (PSG), Boro-Silicate Glass (BSG), Boron-Doped Phospho-Silicate Glass (BPSG), undoped Silicate Glass (USG), or the like.

Conductive plugs 58 extend through the ILD 56 to electrically and physically couple the devices 54. For example, when the devices 54 are transistors, the conductive plugs 58 may couple the gates and source/drain regions of the transistors. The conductive plugs 58 may be formed of tungsten, cobalt, nickel, copper, silver, gold, aluminum, the like, or combinations thereof. An interconnect structure 60 is over the ILD 56 and conductive plugs 58. The interconnect structure 60 interconnects the devices 54 to form an integrated circuit. The interconnect structure 60 may be formed by, for example, metallization patterns in dielectric layers on the ILD 56. The metallization patterns include metal lines and vias formed in one or more low-k dielectric layers. The metallization patterns of the interconnect structure 60 are electrically coupled to the devices 54 by the conductive plugs 58.

The integrated circuit die 50 further includes pads 62, such as aluminum pads, to which external connections are made. The pads 62 are on the active side of the integrated circuit die 50, such as in and/or on the interconnect structure 60. One or more passivation films 64 are on the integrated circuit die 50, such as on portions of the interconnect structure 60 and pads 62. Openings extend through the passivation films 64 to the pads 62. Die connectors 66, such as conductive pillars (for example, formed of a metal such as copper), extend through the openings in the passivation films 64 and are physically and electrically coupled to respective ones of the pads 62. The die connectors 66 may be formed by, for example, plating, or the like. The die connectors 66 electrically couple the respective integrated circuits of the integrated circuit die 50.

Optionally, solder regions (e.g., solder balls or solder bumps) may be disposed on the pads 62. The solder balls may be used to perform chip probe (CP) testing on the integrated circuit die 50. CP testing may be performed on the integrated circuit die 50 to ascertain whether the integrated circuit die 50 is a known good die (KGD). Thus, only integrated circuit dies 50, which are KGDs, undergo subsequent processing and are packaged, and dies, which fail the CP testing, are not packaged. After testing, the solder regions may be removed in subsequent processing steps.

A dielectric layer 68 may (or may not) be on the active side of the integrated circuit die 50, such as on the passivation films 64 and the die connectors 66. The dielectric layer 68 laterally encapsulates the die connectors 66, and the dielectric layer 68 is laterally coterminous with the integrated circuit die 50. Initially, the dielectric layer 68 may bury the die connectors 66, such that the topmost surface of the dielectric layer 68 is above the topmost surfaces of the die connectors 66. In some embodiments where solder regions are disposed on the die connectors 66, the dielectric layer 68 may bury the solder regions as well. Alternatively, the solder regions may be removed prior to forming the dielectric layer 68.

The dielectric layer 68 may be a polymer such as PBO, polyimide, BCB, or the like; a nitride such as silicon nitride or the like; an oxide such as silicon oxide, PSG, BSG, BPSG, or the like; the like, or a combination thereof. The dielectric layer 68 may be formed, for example, by spin coating, lamination, chemical vapor deposition (CVD), or the like. In some embodiments, the die connectors 66 are exposed through the dielectric layer 68 during formation of the integrated circuit die 50. In some embodiments, the die connectors 66 remain buried and are exposed during a subsequent process for packaging the integrated circuit die 50. Exposing the die connectors 66 may remove any solder regions that may be present on the die connectors 66.

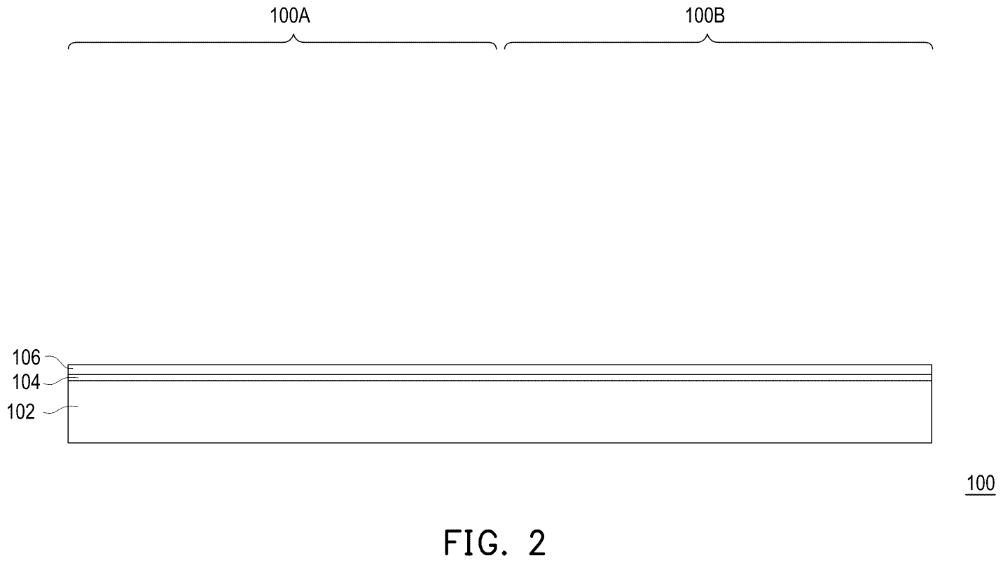

FIGS. 2 through 16C illustrate cross-sectional views of intermediate steps during a process for forming a first package component 100, in accordance with some embodiments. A first package region 100A and a second package region 100B are illustrated, and one or more of the integrated circuit dies 50 are packaged to form an integrated circuit package in each of the package regions 100A and 100B. The integrated circuit packages may also be referred to as integrated fan-out (InFO) packages.

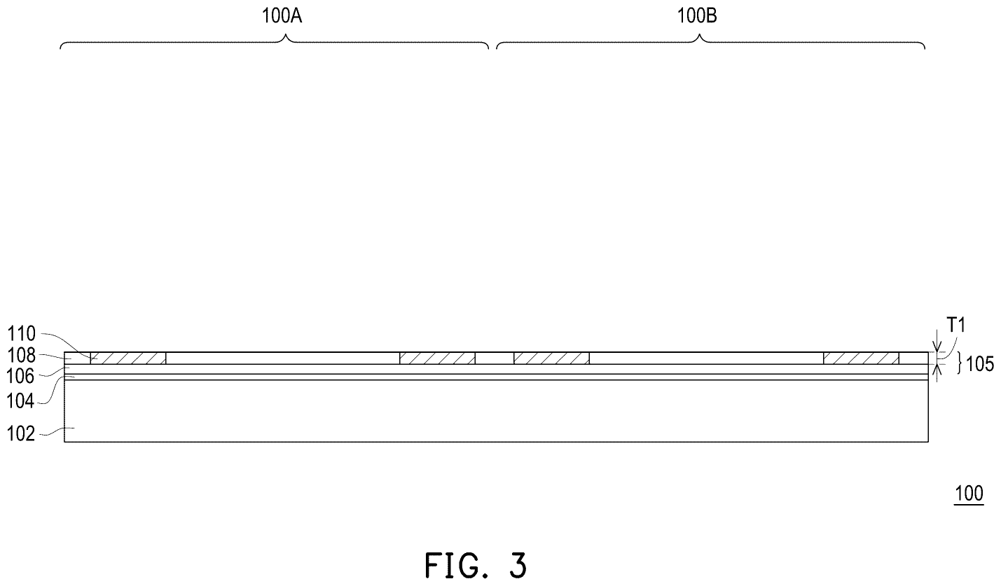

FIGS. 2 and 3 illustrate the formation of a back-side redistribution structure 105 over the carrier substrate 102. In the embodiment shown, the back-side redistribution structure 105 includes a dielectric layer 106, a dielectric layer 108, and a lower redistribution layer (RDL) 110 (sometimes referred to as a metallization pattern) in the dielectric layer 108.

In FIG. 2, a carrier substrate 102 is provided, and a release layer 104 is formed on the carrier substrate 102. The carrier substrate 102 may be a glass carrier substrate, a ceramic carrier substrate, or the like. The carrier substrate 102 may be a wafer, such that multiple packages can be formed on the carrier substrate 102 simultaneously.

The release layer 104 may be formed of a polymer-based material, which may be removed along with the carrier substrate 102 from the overlying structures that will be formed in subsequent steps. In some embodiments, the release layer 104 is an epoxy-based thermal-release material, which loses its adhesive property when heated, such as a light-to-heat-conversion (LTHC) release coating. In other embodiments, the release layer 104 may be an ultra-violet (UV) glue, which loses its adhesive property when exposed to UV lights. The release layer 104 may be dispensed as a liquid and cured, may be a laminate film laminated onto the carrier substrate 102, or may be the like. The top surface of the release layer 104 may be leveled and may have a high degree of planarity.

Still referring to FIG. 2, a dielectric layer 106 is formed on the release layer 104. The dielectric layer 106 may be, for example, a layer of polymer material such as, e.g., polybenzoxazole (PBO), polyimide (PI), benzocyclobutene (BCB), or other polymer material that is electrically insulating. The dielectric layer 106 may be formed using a process such as lamination, coating, (e.g., spin-coating), chemical vapor deposition (CVD), or the like. In some embodiments, the dielectric layer 106 may comprise a glass, a spin-on glass (SOG), a ceramic, low temperature co-fired ceramic (LTCC), silicon oxide, silicon nitride, silicon carbide, silicon oxynitride, or the like.

In FIG. 3, the lower redistribution layer (RDL) 110 is formed on portions of the dielectric layer 106 by initially forming a first seed layer (not shown) of one or more thin layers of a conductive material that aids in the formation of a thicker layer during subsequent processing steps. The first seed layer may comprise a layer of titanium or copper formed using processes such as sputtering, evaporation, PECVD, or the like. A photoresist (also not shown) may then be formed and patterned to cover the first seed layer using, e.g., a spin coating technique. Once the photoresist has been formed and patterned, a conductive material may be formed on the first seed layer. The conductive material may be a material such as copper, titanium, tungsten, aluminum, another metal, the like, or a combination thereof. The conductive material may be formed through a deposition process such as electroplating, electroless plating, or the like. Once the conductive material has been formed, the photoresist may be removed through a suitable removal process such as ashing or chemical stripping. Additionally, after the removal of the photoresist, those portions of the first seed layer that were covered by the photoresist may be removed through, for example, a suitable wet etch process or dry etch process, which may use the conductive material as an etch mask. The remaining portions of the first seed layer and conductive material form the lower redistribution layer (RDL) 110.

After the formation of the lower RDL 110, a dielectric layer 108 is formed over the dielectric layer 106 and the lower RDL 110. The dielectric layer 108 may be, for example, a layer of polymer material such as, e.g., polybenzoxazole (PBO), polyimide (PI), benzocyclobutene (BCB), or other polymer material that is electrically insulating. The dielectric layer 108 may be formed using a process such as lamination, coating, (e.g., spin-coating), chemical vapor deposition (CVD), or the like. In an embodiment, the dielectric layer 106 and the dielectric layer 108 may comprise different materials. In some embodiments, the dielectric layer 108 may comprise a glass, a spin-on glass (SOG), a ceramic, low temperature co-fired ceramic (LTCC), silicon oxide, silicon nitride, silicon carbide, silicon oxynitride, or the like. A planarization step, such as a chemical mechanical polish (CMP), may be performed to remove excess portions of the dielectric layer 108 which are over top surfaces of the lower RDL 110. Accordingly, top surfaces of the lower RDL 110 are exposed, and are level with a top surface of the dielectric layer 108. In an embodiment, a thickness T1 of the lower RDL 110 and the dielectric layer 108 may be in a range from 5 μm to 50 μm.

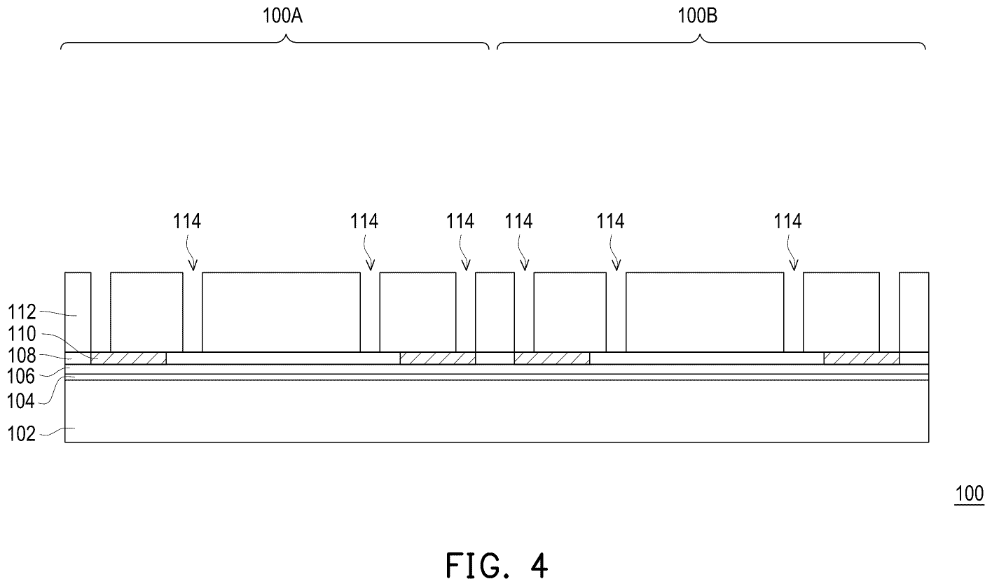

In FIG. 4, a mask layer 112 is formed over the structure shown in FIG. 3, such as over the dielectric layer 108 and the lower RDL 110. The mask layer 112 may be a dry-film photoresist, or the like, and may be formed using a spin on process, a lamination process, or the like. In an embodiment, the mask layer 112 may be formed to have a thickness that is less than 300 μm. The mask layer 112 may be patterned using acceptable development and exposure techniques to form openings (or through holes) 114 in which electrically conductive vias are subsequently formed, according to some embodiments. The vias may be alternatively referred to as pillars or through-insulator-vias or TIVs when spanning an insulating layer. The openings 114 in the mask layer may expose top surfaces of the lower RDL 110 and/or the dielectric layer 108.

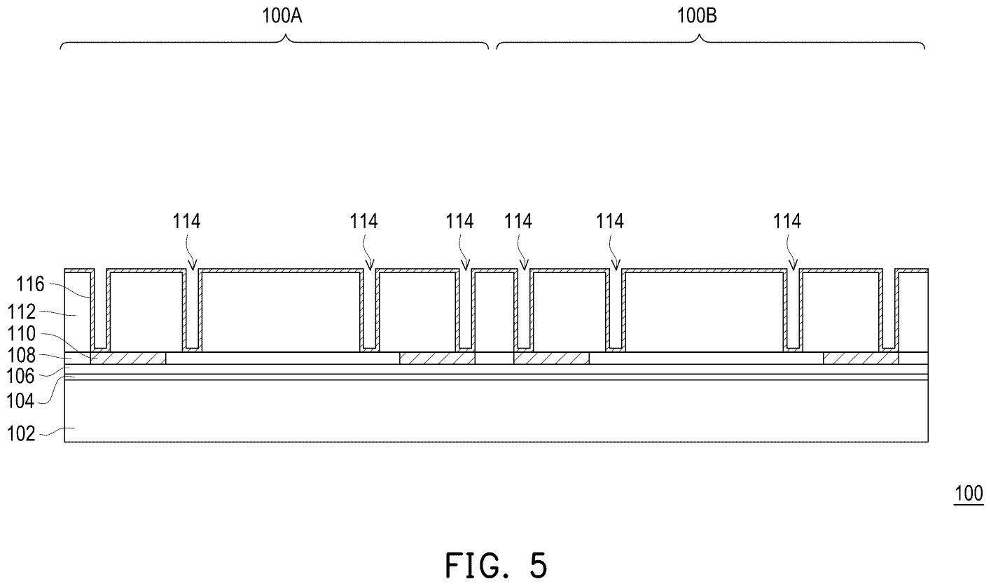

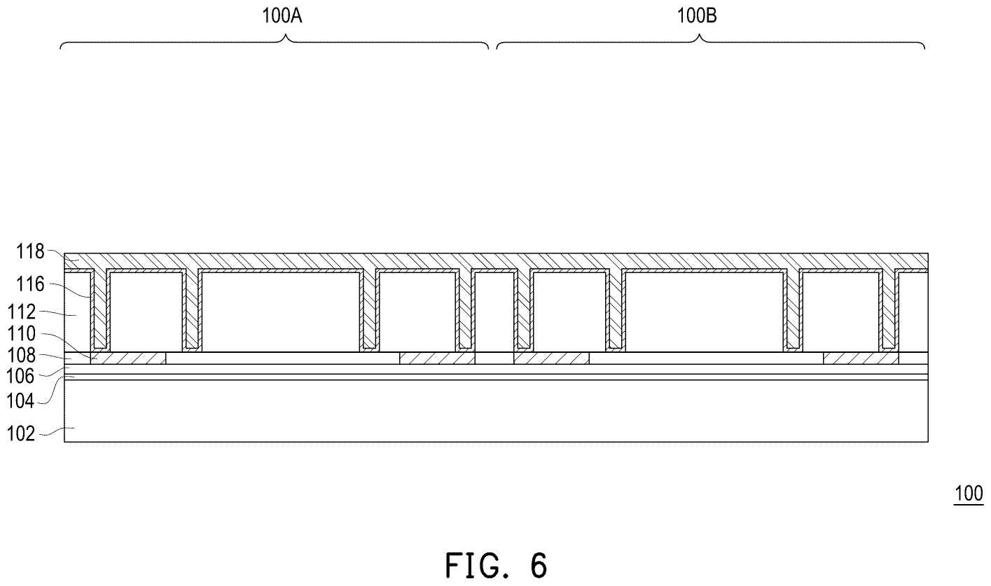

In FIG. 5, a seed layer 116 is formed on the mask layer 112 and in the openings 114 of the mask layer 112, such as on bottom surfaces and sidewalls of the openings 114. The metal seed layer 116 may comprise, for example, a titanium and copper bilayer (e.g., a layer of copper on a layer of titanium), a singular copper layer, or other suitable metal layer, and may be deposited using a CVD process, an ALD process, or the like. Any suitable thickness may be used for the seed layer 116. For example, in some embodiments, the seed layer 116 may comprise a titanium layer that is at least 1000 Å thick and a copper layer that is at least 5000 Å thick. In other embodiments, the seed layer 116 may comprise other combinations of metals and thicknesses.

In FIG. 6, a conductive material 118 is formed on the seed layer 116 and in the openings 114 in order to fill in the openings 114. The conductive material 118 may be a copper layer or other suitable metal formed by an electrochemical plating (ECP) process, or the like. During the ECP process, the conductive material 118 is deposited both laterally on the sidewalls of the openings 114 as well as vertically on bottom surfaces of the openings 114.

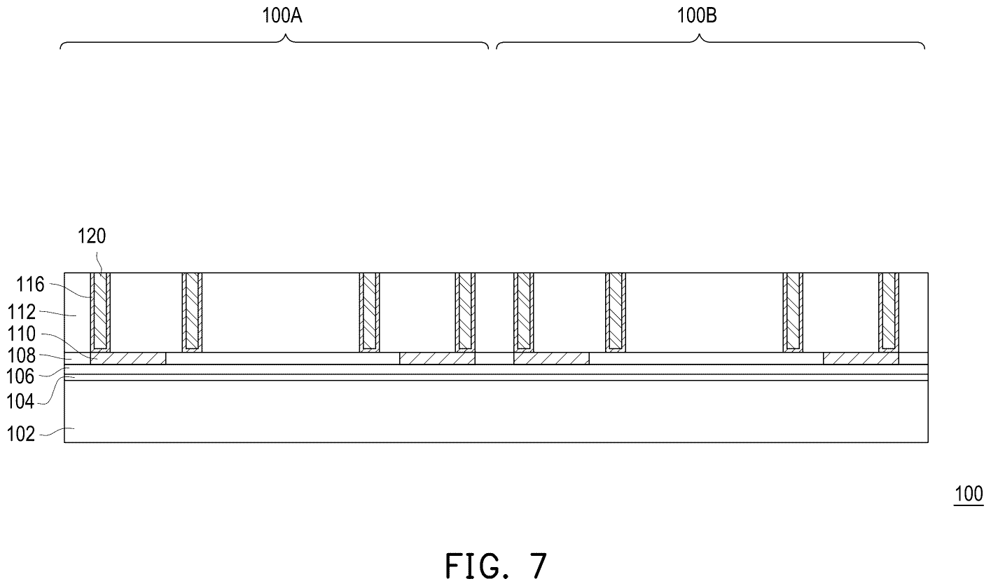

In FIG. 7, a planarization step, such as a chemical mechanical polish (CMP), or the like, may be performed to remove portions of the seed layer 116 and excess portions of the conductive material 118 which are over the mask layer 112. The remaining conductive material 118 and the seed layer 116 in the openings 114 form the plurality of conductive vias 120. Accordingly, after the planarization step, top surfaces of the conductive material 118, the seed layer 116, and the mask layer 112 are level.

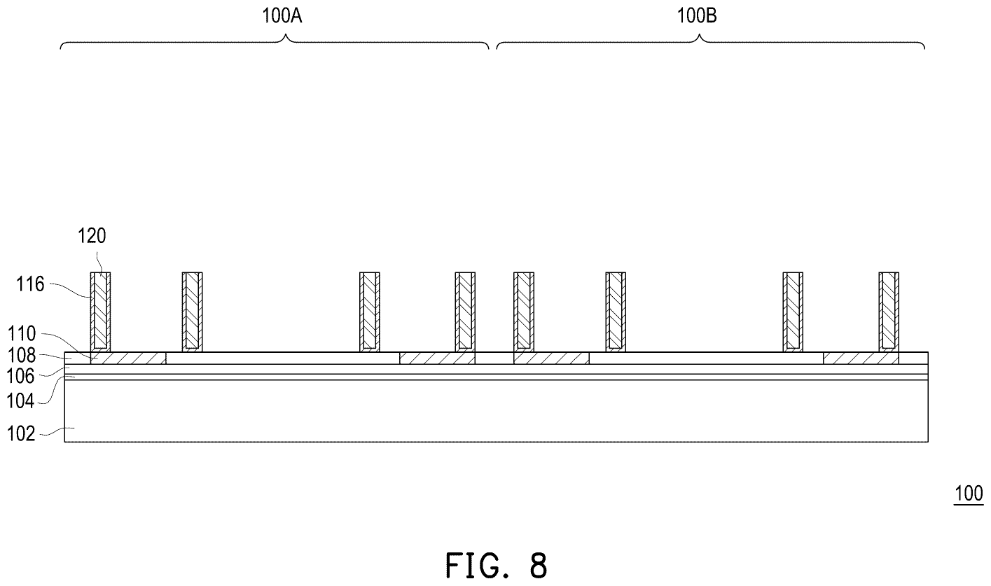

In FIG. 8, after the planarization step, the mask layer 112 may be removed using a suitable removal process such as ashing or chemical stripping.

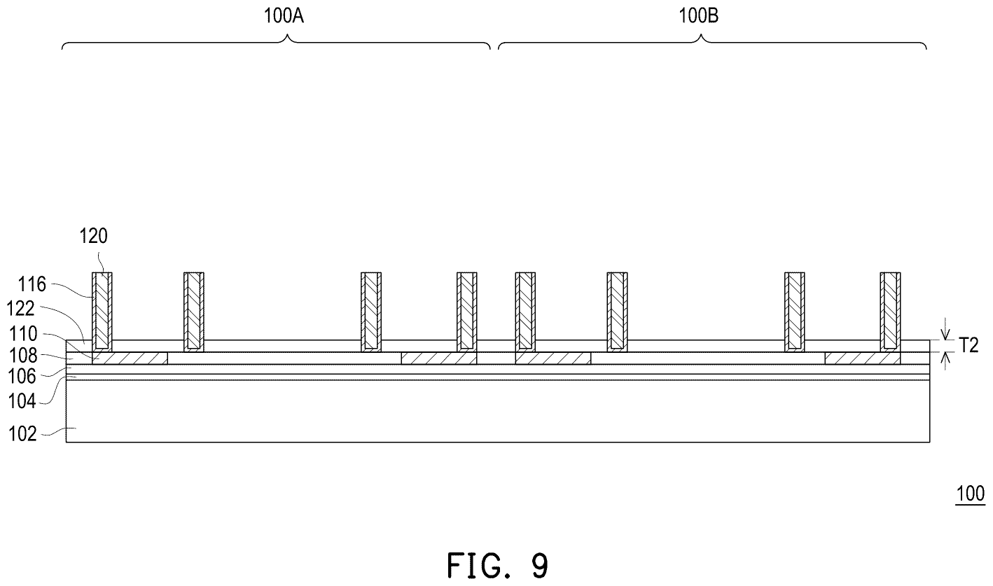

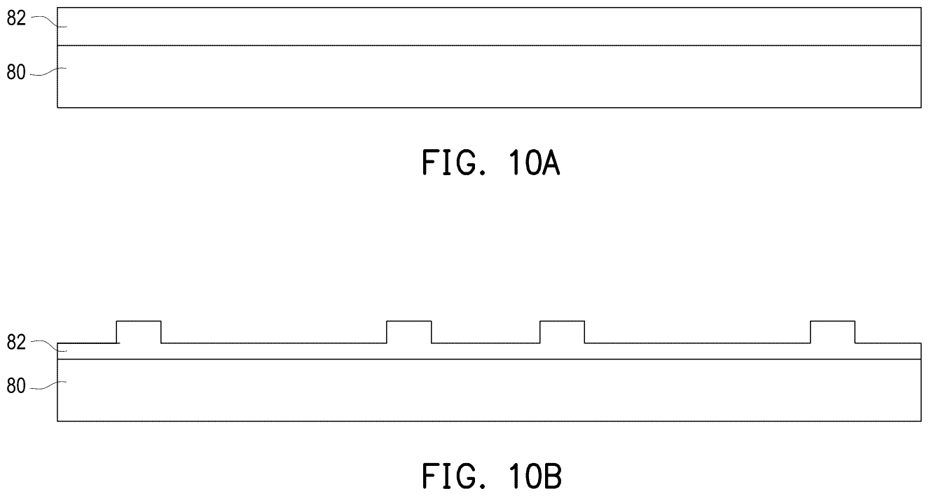

In FIG. 9, a dielectric layer 122 is formed over the dielectric layer 108 and the lower RDL 110. The dielectric layer 122 may be, for example, a layer of polymer material such as, e.g., polybenzoxazole (PBO), polyimide (PI), benzocyclobutene (BCB), or other polymer material that is electrically insulating. The dielectric layer 122 may be formed using a spin-on process, or the like. The use of the spin-on process to form the dielectric layer 122 allows a material of the dielectric layer 122 to be initially formed in a liquid phase over the dielectric layer 108 and the lower RDL 110 and not on top surfaces of the plurality of conductive vias 120. The dielectric layer 122 may then be subsequently cured. In an embodiment, a thickness T2 of the dielectric layer 122 may be in a range from 2 μm to 12 μm.

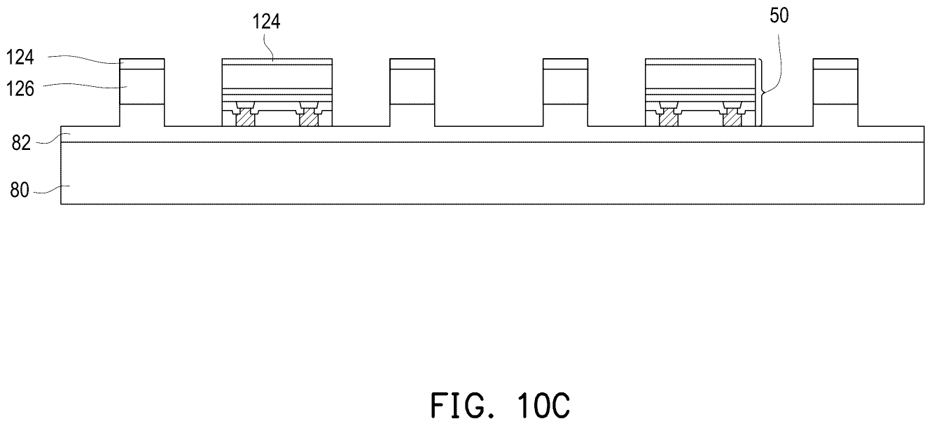

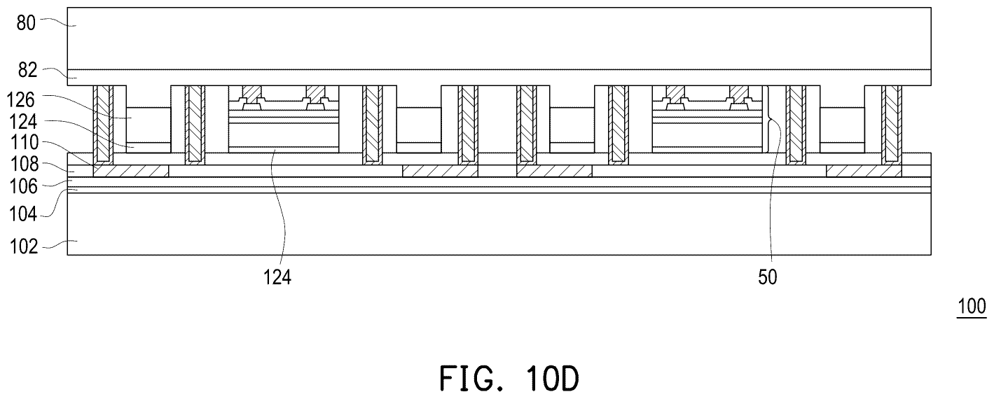

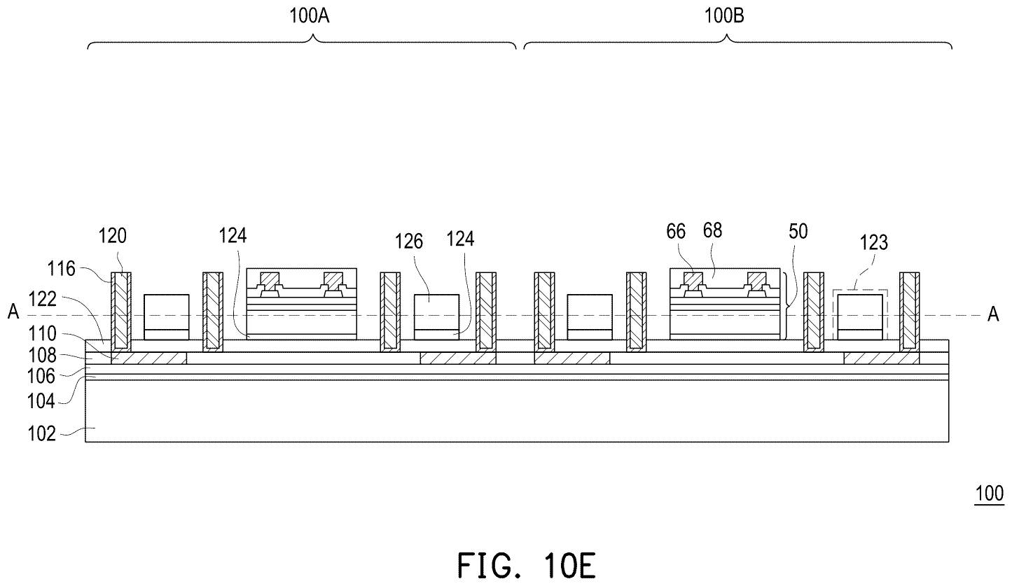

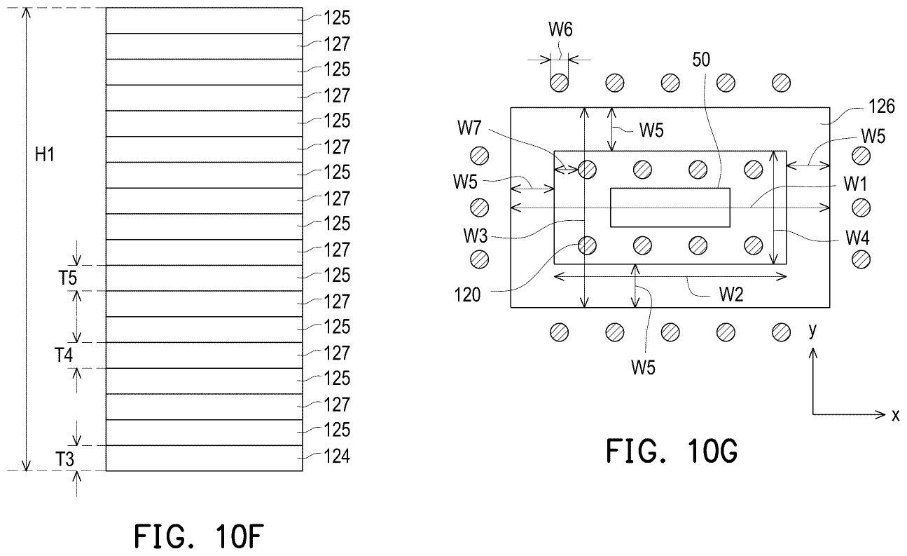

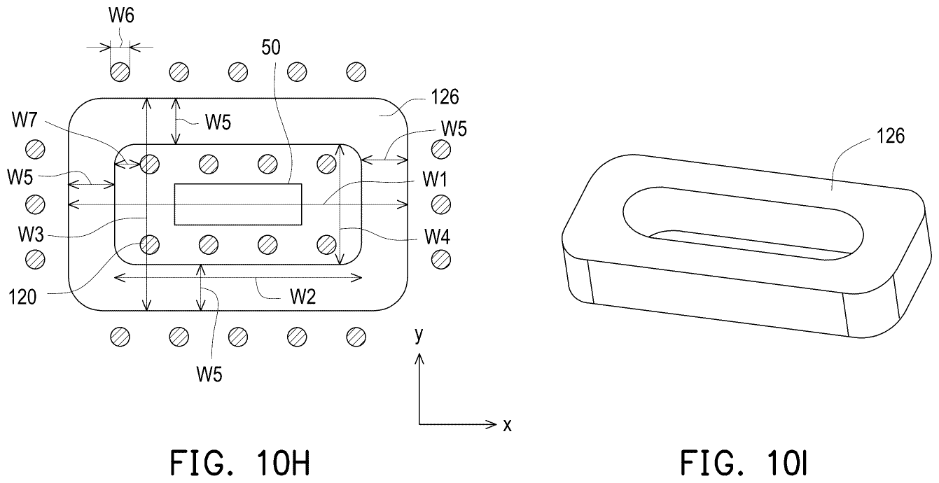

In FIGS. 10A through 10E, a plurality of magnetic solenoid permalloy cores 126 and a plurality of integrated circuit dies 50 are attached to a top surface of the dielectric layer 122 using, for example, a pick and place process, a carrier bonding process, or the like. An example carrier bonding process is illustrated in FIGS. 10A through 10E, but other pick and place processes are also possible for placing the permalloy cores 126 and the integrated circuit dies 50. In FIG. 10A, a carrier substrate 80 is shown. The carrier substrate 80 may comprise silicon-based materials, such as a silicon substrate (e.g., a silicon wafer), a glass material, silicon oxide, or other materials, such as aluminum oxide, the like, or a combination. The carrier substrate 80 may comprise a transparent material such as glass, or the like. An adhesive layer 82 is formed on the carrier substrate 80 to facilitate a subsequent debonding of the carrier substrate 80 from the first package component 100. The adhesive layer 82 may comprise a polymer-based material, which may be removed along with the carrier substrate 80 from the first package component 100. In some embodiments, the adhesive layer 82 may comprise an epoxy-based thermal-release material, which loses its adhesive property when heated, such as a Light-to-Heat-Conversion (LTHC) release coating. In some embodiments, the adhesive layer 82 may comprise an ultra-violet (UV) glue, which loses its adhesive property when exposed to UV light. After the adhesive layer 82 is formed, a suitable curing process may be performed to harden the adhesive material 82.

In FIG. 10B, a mask layer (e.g., a photoresist) is formed over the adhesive layer 82. The mask layer is patterned using suitable development and exposure techniques to form openings in the mask layer that expose top surfaces of the adhesive layer 82. A suitable etching process (e.g., an anisotropic etching process) is then performed to partially etch exposed portions of the adhesive layer 82 using the mask layer as an etching mask. As a result, the adhesive layer 82 may comprise regions with different thicknesses, and the thicknesses can be controlled by varying the parameters of the etching process. After the etching process is performed on the adhesive layer 82, the mask layer may then be removed using an acceptable ashing or stripping process. Although FIG. 10B illustrates an adhesive layer 82 with two different thicknesses, one or more photolithography and etching processes may be used to pattern an adhesive layer 82 with any number of different thicknesses.

In FIG. 10C, the plurality of magnetic solenoid permalloy cores 126 and the plurality of integrated circuit dies 50 are attached to a top surface of the adhesive layer 82 using, for example, a pick and place process, or the like. The plurality of integrated circuit dies 50 are attached to the adhesive layer 82 such that the dielectric layer 68 of each of the plurality of integrated circuit dies 50 faces the adhesive layer 82. The plurality of permalloy cores 126 may be disposed on regions of the adhesive layer 82 that have larger heights than the regions of the adhesive layer 82 on which the plurality of integrated circuit dies 50 are disposed on. As a result, topmost surfaces of the plurality of permalloy cores 126 and topmost surfaces of the plurality of integrated circuit dies 50 are level. The plurality of integrated circuit dies 50 and the plurality of permalloy cores 126 may also comprise a die attach films (DAF) 124 that are disposed on top surfaces of the plurality of integrated circuit dies 50 and the plurality of permalloy cores 126. The DAF 124 may comprise a polymer material. In FIG. 10D, the carrier substrate 80 and the first package component 100 are then transported to a bond chamber where the carrier substrate 80 is oriented to align the plurality of permalloy cores 126 and the plurality of integrated circuit dies 50 with the plurality of conductive vias 120, such that the plurality of permalloy cores 126 and the plurality of integrated circuit dies 50 face the dielectric layer 122. The plurality of permalloy cores 126 and the plurality of integrated circuit dies 50 are pressed against the dielectric layer 122 to couple the plurality of permalloy cores 126 and the plurality of integrated circuit dies 50 to the dielectric layer 122 using the die attach films (DAFs) 124. A first anneal process is then performed in the bond chamber to initiate bonding of the DAF films 124 with the dielectric layer 122. As a result, the plurality of permalloy cores 126 and the plurality of integrated circuit dies 50 are adhered to the dielectric layer 122. The first anneal may be performed at a temperature in a range from 150° C. to 350° C. and for a duration of time that is in a range from 0.5 hours to 4 hours.

In FIG. 10E, a de-bonding of the carrier substrate 80 is then performed to detach (or “de-bond”) the carrier substrate 80 from the plurality of permalloy cores 126 and the plurality of integrated circuit dies 50. In accordance with some embodiments, the de-bonding includes projecting a light such as a laser light or an UV light on the adhesive layer 82 so that the adhesive layer 82 decomposes under the heat of the light. The carrier substrate 80 can then be mechanically removed leaving the plurality of permalloy cores 126 and the plurality of integrated circuit dies 50 bonded to the dielectric layer 122. After the removal of the carrier, a second anneal may be performed at a temperature in a range from 150° C. to 350° C. and for a duration of time that is in a range from 0.5 hours to 4 hours. The second anneal strengthens the bonding between the plurality of permalloy cores 126 and the dielectric layer 122. The second anneal also strengthens the bonding between the plurality of integrated circuit dies 50 and the dielectric layer 122. In other embodiments, the second anneal maybe performed before the removal of the carrier. Although FIGS. 10A though 10E illustrate that the plurality of permalloy cores 126 and the plurality of integrated circuit dies 50 are bonded to the top surface of the dielectric layer 122 simultaneously using the carrier substrate 80, the plurality of integrated circuit dies 50 may be bonded to the top surface of the dielectric layer 122 either prior to or after the plurality of permalloy cores 126 are bonded to the top surface of the dielectric layer 122. In such a case, the bonding of the plurality of integrated circuit dies 50 to the top surface of the dielectric layer 122 may be performed with a first carrier substrate, and the bonding of the plurality of permalloy cores 126 to the top surface of the dielectric layer 122 may be performed with a second carrier substrate different from the first carrier substrate.

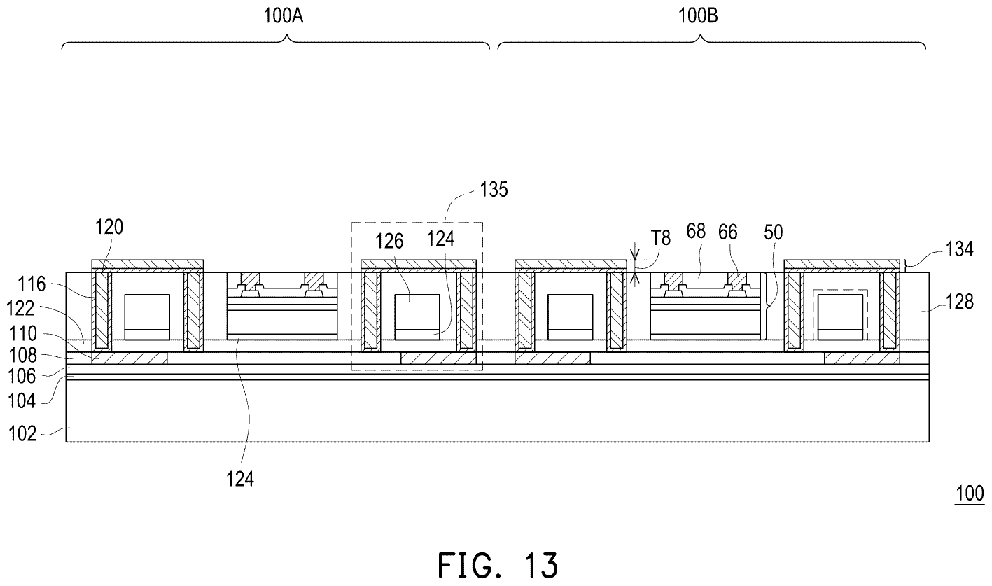

Each of the plurality of permalloy cores 126 may comprise a magnetic bar having a shape of a closed loop (e.g., having a rectangular shaped loop, square shaped loop, triangle shaped loop or toroidal shaped loop) when seen in a top-view (for example, as illustrated in FIGS. 10G and 10H) and is disposed such that the closed loop encircles the entire perimeter of at least one of the plurality of integrated circuit dies 50. Each of the plurality of permalloy cores 126 is disposed such that inner sidewalls and outer sidewalls of the permalloy core 126 are surrounded by the plurality of conductive vias 120. In addition, each of the plurality of permalloy cores 126 is sandwiched between the lower RDL 110 below the permalloy core 126 and subsequently formed upper RDL 134 (shown in FIG. 13) above the permalloy core 126.

FIG. 10F illustrates a detailed view of a region 123 of the FIG. 10E and illustrates a portion of one of the plurality of permalloy cores 126. As illustrated in FIG. 10F, each of the plurality of permalloy cores 126 includes a magnetic bar comprising a plurality of alternating layers that are vertically stacked. The plurality of alternating layers include permalloy layers 127 and epoxy layers 125, such that each permalloy layer 127 is disposed between two epoxy layers 125. In an embodiment, each of the plurality of permalloy cores 126 comprises at least eight permalloy layers 127. In other embodiments, each of the plurality of permalloy cores 126 comprises any number of permalloy layers 127. A topmost layer and a bottommost layer of the plurality of alternating layers is an epoxy layer 125, and the plurality of permalloy cores 126 are attached to the dielectric layer 122 using the die attach film (DAF) 124. The plurality of permalloy cores 126 can also subsequently be referred to as a plurality of “laminated permalloy cores”. Each of the plurality of permalloy cores 126 may comprise a magnetic bar that is formed to be in the shape of a closed loop (e.g., having a toroidal shaped loop, rectangular shaped loop, square shaped loop, triangle shaped loop, or the like), or may comprise a plurality of closed loops. In some embodiments, the term “permalloy” may be replaced by “Mo-permalloy”, “Mumetal”, “Ultraperm” or “Super-malloy”. In some embodiments, each of the plurality of permalloy cores 126 has high magnetic permeability. For example, in some embodiments, a magnetic permeability of each of the plurality of permalloy cores 126 is in a range from 1000 μm to 1,000,000 μm. In some embodiments, the permalloy layers 127 comprises Ni, Fe, Co, Mo, Si, Nb, B, or a combination thereof. For example, each permalloy layer 127 may be an alloy formed by at least two of these elements. In other embodiments, each permalloy layer 127 may be an alloy formed by at least one of the materials listed above and other materials not listed. In an embodiment, each permalloy layer 127 may comprise CoFeB. The epoxy layers 125 may comprise polymers such as epoxy resins, or the like, which have undergone a curing process. In an embodiment, a thickness T3 of the die attach film 124 is at least 5 μm. In an embodiment, a thickness T4 of each permalloy layer 127 is in a range from 1 μm to 50 μm. In an embodiment, a thickness T5 of each epoxy layer 125 is in a range from 1 μm to 10 μm. In an embodiment, each of the plurality of permalloy cores 126 may have a height H1 that is in a range from 50 μm to 500 μm. Advantages can be achieved by each permalloy layer 127 of the plurality of permalloy cores 126 having the thickness T4 that is in a range from 1 μm to 50 μm, and each epoxy layer 125 of the plurality of permalloy cores 126 having a thickness T5 that is in a range from 1 μm to 10 μm. These include an increased magnetic permeability of each of the plurality of permalloy cores 126, which allows for a higher inductance.

FIG. 10G illustrates a top view of one of the plurality of permalloy cores 126 in accordance with various embodiments. FIG. 10G is illustrated in a way that identifies a first direction (e.g., the x-direction), and a second direction (e.g., the −y direction), wherein the second direction is orthogonal to the first direction. The second direction (e.g., the y-direction) is along a similar line to the line A-A shown in FIG. 10E. FIG. 10G shows that each of the plurality of permalloy cores 126 may comprise a magnetic bar in the form of a closed loop having a rectangular shaped loop when seen in a top-down view. The closed loop is disposed such that it encircles the entire perimeter of the integrated circuit die 50. In other embodiments (not shown in the Figures), the closed loop may have a circular, ovular, triangular, or square shape. In an embodiment, the closed loop may have a width W1 in the first direction (e.g., along the x-direction) between a first outermost sidewall of the closed loop and a second outermost sidewall of the closed loop, wherein the width W1 is in a range from 15 μm to 2400 μm. The closed loop may have a width W2 in the first direction (e.g., the x-direction) between a first inner sidewall of the closed loop and a second inner sidewall of the closed loop, wherein the width W2 is in a range from 5 μm to 2000 μm. The closed loop may have a width W3 in the second direction (e.g., along the y-direction) between a third outermost sidewall of the closed loop and a fourth outermost sidewall of the closed loop, wherein the width W3 is in a range from 15 μm to 1400 μm. The closed loop may have a width W4 in the second direction (e.g., the y-direction) between a third inner sidewall of the closed loop and a fourth inner sidewall of the closed loop, wherein the width W4 is in a range from 5 μm to 1000 μm. In an embodiment, a width W5 in the first direction between the first outermost sidewall and a nearest inner sidewall to the first outermost sidewall of the closed loop is in a range from 5 μm to 200 μm. A width in the first direction between the second outermost sidewall and a nearest inner sidewall to the second outermost sidewall of the closed loop is equal to W5. A width in the second direction between the third outermost sidewall and a nearest inner sidewall to the third outermost sidewall of the closed loop is equal to W5. A width in the second direction between the fourth outermost sidewall and a nearest inner sidewall to the fourth outermost sidewall of the closed loop is equal to W5. The plurality of conductive vias 120 disposed within an inner perimeter of the closed loop of the permalloy core 126 and the plurality of conductive vias 120 disposed outside an outer perimeter of the closed loop of the permalloy core 126 form part of a conductive trace of a 3D inductor 135 (shown subsequently in FIG. 13) that is wound around the permalloy core 126. In an embodiment, a width W6 of each of the plurality of conductive vias 120 may be in a range from 5 μm to 15 μm. In an embodiment, a width W7 between an inner sidewall of the permalloy core 126 and a closest sidewall of one of the plurality of conductive vias 120 disposed within an inner perimeter of the closed loop of the permalloy core 126 may be in a range from 5 μm to 15 μm. In an embodiment, a width between an outer sidewall of the permalloy core 126 and a closest sidewall of one of the plurality of conductive vias 120 disposed outside an outer perimeter of the closed loop of the permalloy core 126 may be in a range from 5 μm to 15 μm.

FIG. 10H illustrates a top view of one of the plurality of permalloy cores 126, and FIG. 10I illustrates a perspective view of the one of the plurality of permalloy cores 126, in accordance with other embodiments. Unless specified otherwise, like reference numerals in this embodiment (and subsequently discussed embodiments) represent like components in the embodiment shown in FIGS. 1 through 10G formed by like processes. FIGS. 10H and 10I shows that each of the plurality of permalloy cores 126 may comprise a magnetic bar in the form of a closed loop having a rectangular shape when seen in a top-view, wherein outer corners and inner corners of the closed loop may be rounded. In other embodiments, the closed loop may have a toroidal shape.

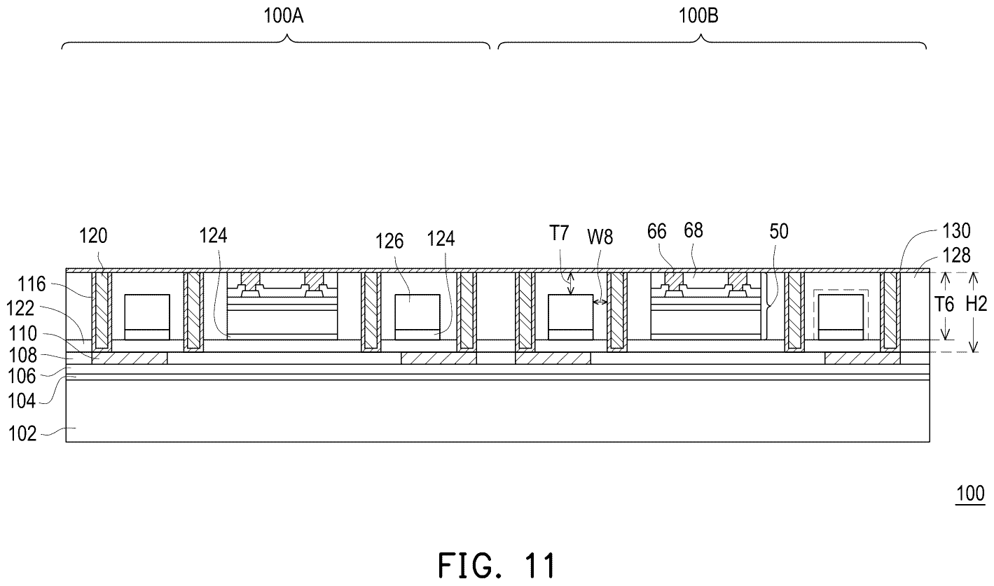

In FIG. 11, an electrically insulating molding material (or molding compound) 128 is formed over the structure shown in FIG. 10E, such as on top surfaces and sidewalls of the plurality of conductive vias 120, top surfaces and sidewalls of the plurality of permalloy cores 126, top surfaces and sidewalls of the plurality of integrated circuit dies 50, sidewalls of the die attach film (DAF) 124, and top surfaces of the dielectric layer 122. The molding material 128 can comprise a dielectric material, such as silicon based material, an epoxy molding compound that includes silica, or the like, that provides electrical isolation between each of the plurality of conductive vias 120 and other structures of the first package component 100. In an embodiment, a width W8 of the molding material 128 between a sidewall of each of the plurality of permalloy cores 126 and a sidewall of a nearest one of the plurality of conductive vias 120 is at least 5 μm. The molding material 128 can be formed according to various formation techniques, such as a spin-on process, a deposition process, an injection process, or the like. Excess portions of the molding material 128 may then be planarized by grinding and CMP to remove a portion of the molding material 128 and expose top surfaces of the plurality of conductive vias 120. During the planarization, a portion of the dielectric layer 68 of each of the plurality of integrated circuit dies 50 may also be removed so as to expose top surfaces of the die connectors 66. As illustrated in FIG. 11, the planarization may result in the top surfaces of the plurality of conductive vias 120 and the die connectors 66 being level with a top surface of the molding material 128. However, top surfaces of the plurality of permalloy cores 126 may remain covered by the molding material 128 after planarization. In an embodiment, after the planarization, a height H2 of each of the plurality of conductive vias 120 may be in a range from 50 μm to 500 μm. In an embodiment, after the planarization, a thickness T6 of the molding material 128 may be in a range from 50 μm to 500 μm. In an embodiment, after the planarization, a thickness T7 of the molding material 128 above a top surface of each of the plurality of permalloy cores 126 may be at least 10 μm. The molding material 128 having a thickness that is smaller than 10 μm above the top surface of each of the plurality of permalloy cores 126 will lead to insufficient insulation between the plurality of permalloy cores 126 and a subsequently formed upper RDL 134 of a 3D inductor 135 (shown in FIG. 13). This will result in reduced performance and reduced inductance values of the 3D inductor 135.

Still referring to FIG. 11, a seed layer 130 is formed on top surfaces of the molding material 128, top surfaces of the plurality of conductive vias 120, and top surfaces of the plurality of integrated circuit dies 50. The metal seed layer 130 may comprise, for example, a titanium and copper bilayer (e.g., a layer of copper on a layer of titanium), a singular copper layer, or other suitable metal layer, and may be deposited using a PVD process, a CVD process, an ALD process, or the like. Any suitable thickness may be used for the seed layer 130. For example, in some embodiments, the seed layer 130 may comprise a titanium layer that is at least 500 Å thick and a copper layer that is at least 3000 Å thick. In other embodiments, the seed layer 130 may comprise other combinations of metals and thicknesses. The seed layer 130 is part of a subsequently formed front-side redistribution structure 149 (see FIG. 14) over the molding material 128, top surfaces of the plurality of conductive vias 120, and top surfaces of the plurality of integrated circuit dies 50.

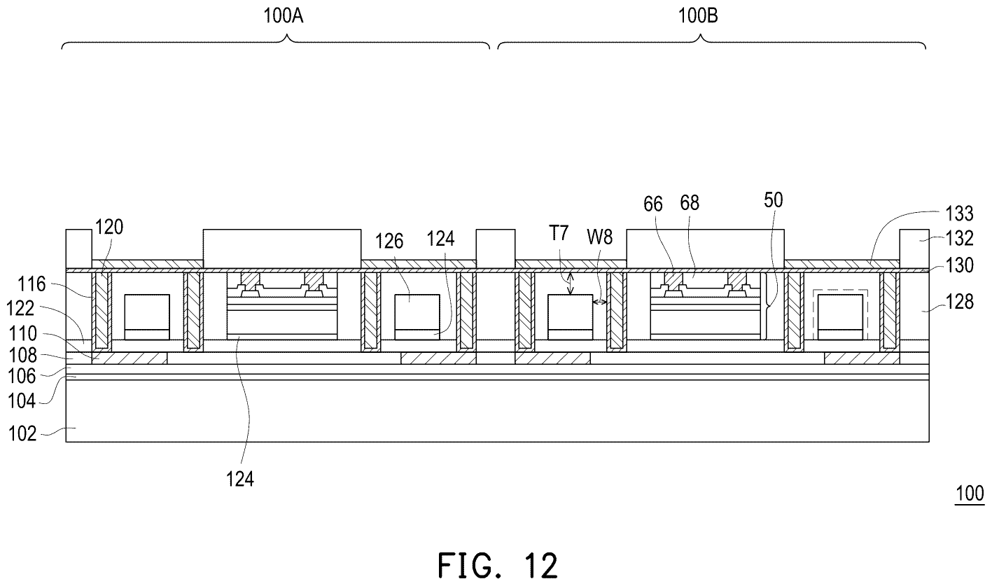

In FIG. 12, a mask layer 132 is formed on the seed layer 130. The mask layer 132 may be a photoresist, or the like, and may be formed using a spin coating or deposition process. The mask layer 132 is then patterned using acceptable development and exposure techniques to form openings that expose portions of the seed layer 130 that overlap the plurality of conductive vias 120 and the plurality of permalloy cores 126. A conductive material layer 133 is then deposited on the portions of the seed layer 130 that are exposed by the openings of the mask layer 132. The conductive material 133 may be copper, or the like, that is deposited using a plating process, for example, electroplating, electroless plating, immersion plating, or the like. In an embodiment, a timed electroplating process is used to deposit the conductive material 133.

In FIG. 13, the mask layer 132 may be removed through a stripping process, an etching process, and/or a cleaning process. In an embodiment, the mask layer 132 may be removed using a solution that comprises dimethyl sulfoxide (DMSO), water (H₂O), and tetramethyl ammonium hydroxide (TMAH). The TMAH compounds are able to break the cross-linkage of molecules within the mask layer 132, and the DMSO compounds then dissolve the molecules within the mask layer 132 and facilitate its removal.

Still referring to FIG. 13, after the removal of the mask layer 132, portions of the seed layer 130 that were covered by the mask layer 132 are exposed. The exposed portions of the seed layer 130 are removed through an etching process. In some embodiments, the etching process may include an anisotropic etching process such as a dry etch or an isotropic etching process such as a wet etch. In some embodiments, an etchant for the wet etch comprises a combination of hydrogen fluoride (HF), copper (Cu), and ammonia (NH₃). In other embodiments, the etchant for the wet etch comprises a combination of HF and TMAH. The remaining portions of the seed layer 130 and the overlying conductive material 133 form an upper redistribution layer (RDL) 134 (which also maybe referred to as a metallization pattern). In an embodiment, a thickness T8 of the upper RDL 134 may be in a range from 5 μm to 50 μm. Portions of the upper RDL 134 are each electrically connected to respective ones of the plurality of conductive vias 120, and the respective ones of the plurality of conductive vias 120 are electrically connected to a respective portion of the lower RDL 110, so as to yield a plurality of 3D inductors 135. Each of the plurality of 3D inductors 135 comprises a conductive trace that forms a coil that is wound around a top surface, a bottom surface, outer sidewalls and inner sidewalls of each of the plurality of permalloy cores 126. The conductive trace of each of the plurality of 3D inductors 135 comprises a portion of the lower RDL 110, respective ones of the plurality of conductive vias 120, and a respective portion of the upper RDL 134.

Advantages can be achieved as a result of the first package component 100 comprising a 3D inductor 135 that includes the permalloy core 126. The permalloy core 126 comprises the plurality of vertically stacked alternating layers that include the permalloy layers 127 and the epoxy layers 125, such that each permalloy layer 127 is disposed between two epoxy layers 125. The permalloy core 126 comprises at least eight permalloy layers 127, wherein the thickness of each permalloy layer 127 is in a range from 1 μm to 50 μm, and the thickness of each epoxy layer 125 is in a range from 1 μm to 10 μm. The permalloy core 126 is a magnetic bar that is formed to be in the shape of a closed loop (e.g., having a toroidal loop shape, rectangular loop shape, square loop shape, or the like), or may comprise a plurality of closed loops. These advantages include an increased magnetic permeability of the permalloy core 126, which results in a higher inductance. The permalloy core 126 comprising a plurality of closed loops also allows for the achievement of increased inductances. Further, the disclosed method may provide a more efficient and more compact 3D inductor 135 that can be integrated easily into existing processes and provide improved inductor performance with lower manufacturing costs and reduced spacing needs.

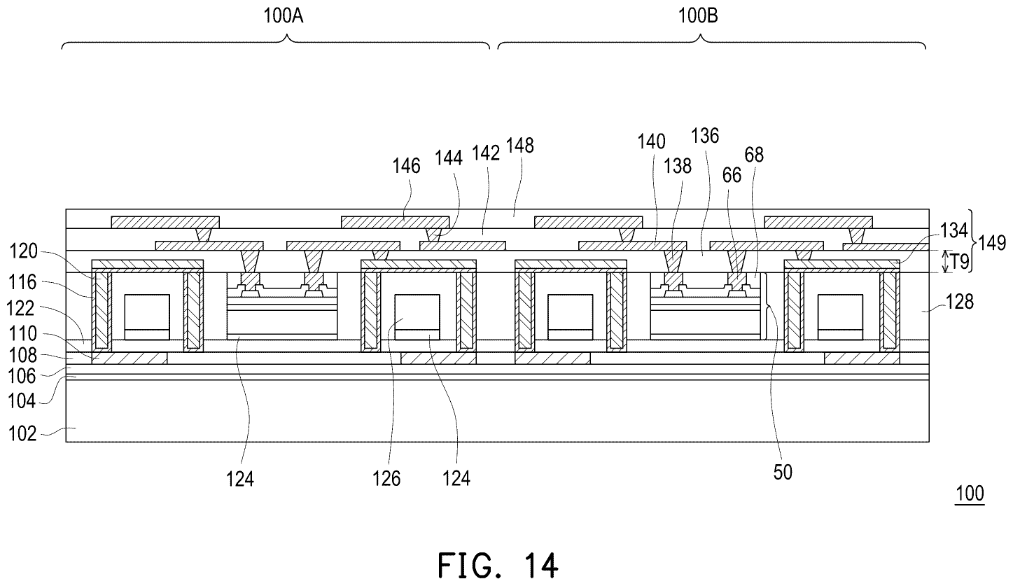

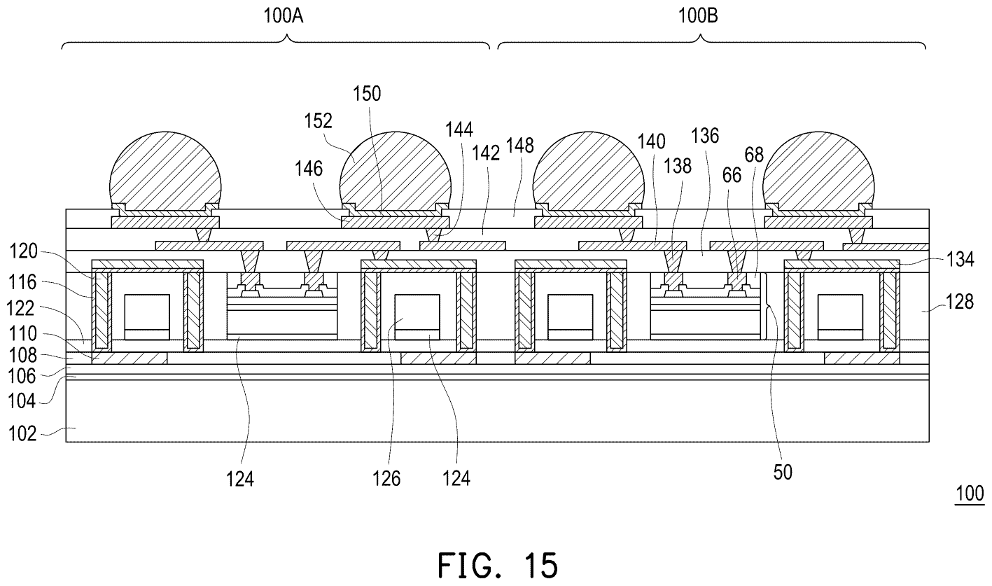

In FIGS. 14 and 15, Additional exemplary processing will now be described for providing additional redistribution layers of the front-side redistribution structure 149, and conductive connectors 152 to provide for input/output (I/O) to die circuitry and electrical I/O to each of the plurality of 3D inductors 135.

In FIG. 14, a dielectric layer 136 is formed over the upper RDL 134 and the molding material 128, such that the upper RDL 134 is embedded in the dielectric layer 136. The dielectric layer 136 may be formed using similar processes and comprise similar materials as the dielectric layer 108 that was described earlier in FIG. 3. In an embodiment, a thickness T9 of the dielectric layer 136 may be in a range from 5 μm to 50 μm. A first mask layer (e.g., a photoresist) may be formed over the dielectric layer 136 and subsequently patterned to expose top surfaces of the dielectric layer 136. A suitable etching process is then performed using the first mask layer as an etching mask to form openings in the dielectric layer 136 that expose top surfaces of the upper RDL 134 and the die connectors 66. A first seed layer (not shown in FIG. 14) that may comprise, for example, a titanium and copper bilayer (e.g., a layer of copper on a layer of titanium), a singular copper layer, or other suitable metal layer, and may be deposited using a CVD process, an ALD process, or the like,, may be deposited in the openings, such as on sidewalls of the openings and on the exposed top surfaces of the upper RDL 134 and the die connectors 66. A first conductive material may then be deposited on the first seed layer in the openings using a plating process, such as electroplating or electroless plating. The first conductive material may comprise copper, titanium, or the like. The first mask layer may then be removed using an acceptable ashing or stripping process.

After the removal of the first mask layer, a planarization step, such as a chemical mechanical polish (CMP), may be performed to remove excess portions of the first seed layer and the first conductive material that are over top surfaces of the dielectric layer 136. The remaining first seed layer and the first conductive material in the openings forms the vias 138. The vias may be alternatively referred to as through-insulator-vias or TIVs. Accordingly, top surfaces of the dielectric layer 136 are level with top surfaces of the vias 138.

A second mask layer (e.g., a photoresist) may then be formed over the dielectric layer 136 and the vias 138. The second mask layer may be patterned to form openings that expose top surfaces of the vias 138. A second seed layer is formed in the openings in the second mask layer. The second seed layer may comprise, for example, a Ti/Cu bilayer, a copper layer, or other suitable metal layer, and may be deposited using a PVD process (e.g., sputtering) or the like. A second conductive material may then be deposited on the second seed layer to form redistribution layer (RDL) 140 (sometimes referred to as a metallization pattern). The second conductive material may comprise copper, titanium, or the like, and may be formed using a plating process, such as electroplating or electroless plating. The second mask layer may then be removed using an acceptable ashing or stripping process. The RDL 140 is electrically connected to the plurality of integrated circuit dies 50 and the upper RDL 134 through the vias 138.

Referring further to FIG. 14, a dielectric layer 142 is formed over the dielectric layer 136 and the RDL 140, such that the RDL 140 is embedded in the dielectric layer 142. The dielectric layer 142 may be formed using a similar process and similar materials as those described above for the formation of the dielectric layer 136. Vias 144 are then formed in the dielectric layer 142, and a redistribution layer (RDL) 146 is formed on the dielectric layer 142 using similar processes and similar materials as described above for the formation of the vias 138 and the RDL 140.

After the formation of the RDL 146 and the vias 138, a dielectric layer 148 is formed over the RDL 146 and the dielectric layer 144, such that the RDL 146 is embedded in the dielectric layer 148. The dielectric layer 148 may be formed using similar processes and comprise similar materials as the dielectric layer 136 and the dielectric layer 142 that were described above. The front-side redistribution structure 149 is shown as an example having three layers of metallization patterns. More or fewer dielectric layers and metallization patterns may be formed in the front-side redistribution structure 149. If fewer dielectric layers and metallization patterns are to be formed, steps and process discussed above may be omitted. If more dielectric layers and metallization patterns are to be formed, steps and processes discussed above may be repeated.

In FIG. 15, the dielectric layer 148 is patterned using acceptable photolithography and etching techniques to form openings in the dielectric layer 148 that expose top surfaces of the RDL 146. A conductive metal such as copper, titanium, or the like, is deposited over the dielectric layer 148 and in the openings in the dielectric layer 148 using for example, sputtering, evaporation, PECVD, or the like. Suitable photolithographic masking and etching process are then used to remove portions of the conductive metal, and the remaining portions of the conductive metal form the under ball metal (UBM) pads 150. Conductive connectors 152 are formed on the UBM pads 150. The conductive connectors 152 may be solder balls, metal pillars, metal vias, or the like. The conductive connectors 152 may include a conductive material such as solder, or the like. In some embodiments, the conductive connectors 152 are formed by initially forming a layer of solder through evaporation, electroplating, printing, solder transfer, ball placement, or the like. Once a layer of solder has been formed on the structure, a reflow may be performed in order to shape the material into the desired bump shapes. The conductive connectors 152 provide for electrical input/output (I/O) to circuitry of each of the plurality of integrated circuit dies 50 and each of the plurality of 3D inductors 135.

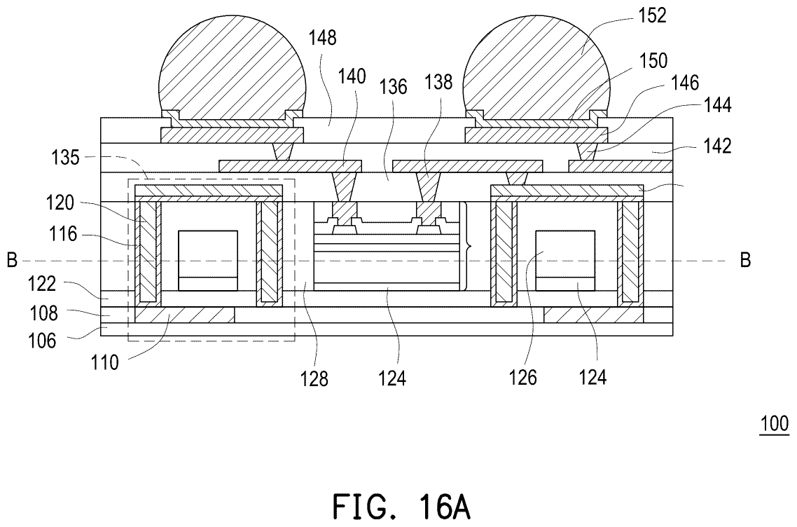

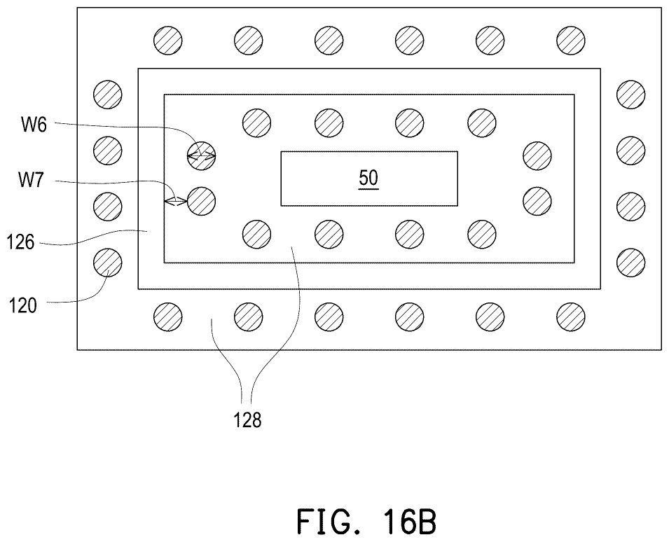

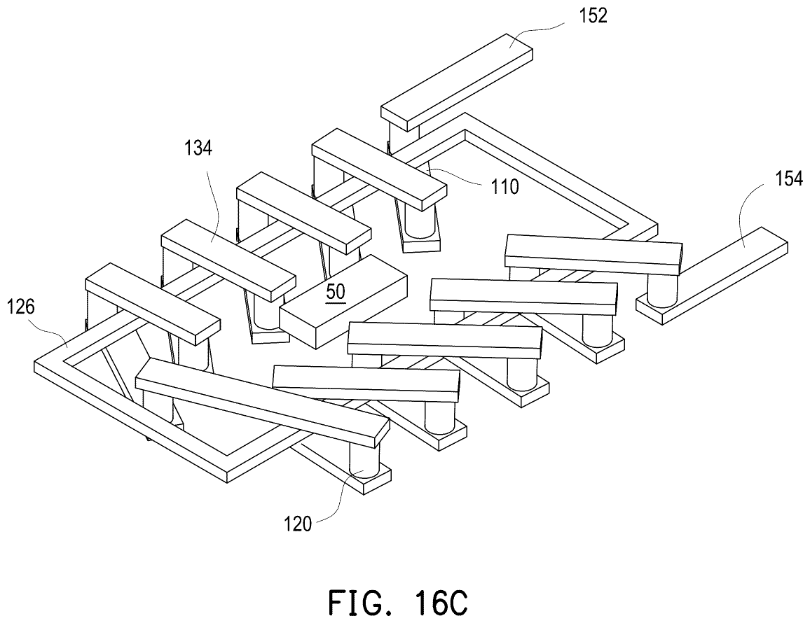

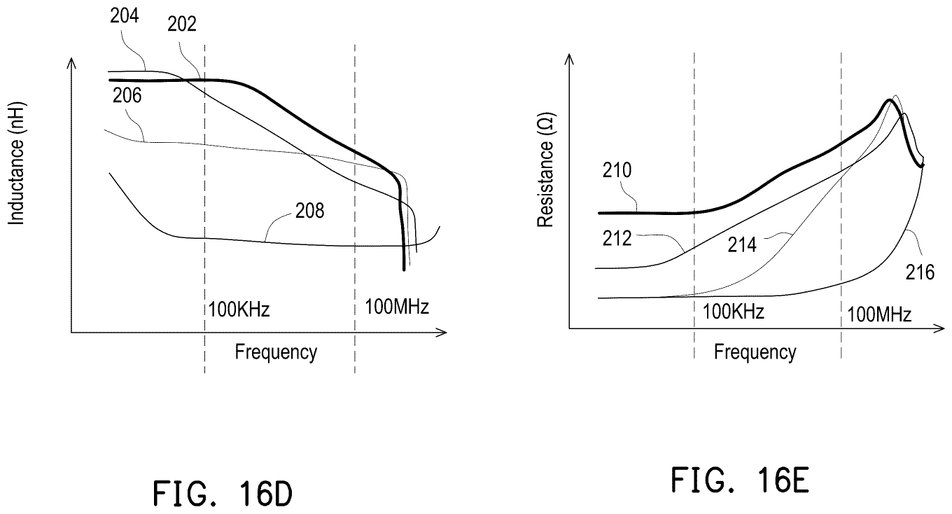

In FIG. 16A, a carrier substrate de-bonding is performed to detach (or “de-bond”) the carrier substrate 102 from the back-side redistribution structure 105, e.g., the dielectric layer 106. In accordance with some embodiments, the de-bonding includes projecting a light such as a laser light or an UV light on the release layer 104 so that the release layer 104 decomposes under the heat of the light and the carrier substrate 102 can be removed. The dielectric layer 106 provides protection at the bottom side of the first package component 100. After the carrier substrate 102 is de-bonded from the back-side redistribution structure 105, a singulation process is then performed by sawing along scribe line regions, e.g., between the first package region 100A and the second package region 100B. The sawing singulates the first package region 100A from the second package region 100B. The resulting, singulated device stack is from one of the first package region 100A or the second package region 100B.

FIG. 16B illustrates a top-down view of a cross-section of the first package component 100 along a line B-B shown in FIG. 16A. As illustrated in FIG. 16B, the permalloy core 126 is separated from the integrated circuit die 50 and the plurality of conductive vias 120 by the molding material 128. The plurality of conductive vias 120 disposed within an inner perimeter of the closed loop of the permalloy core 126 and the plurality of conductive vias 120 disposed outside an outer perimeter of the closed loop of the permalloy core 126 form part of a conductive trace of a 3D inductor 135 that is wound around the permalloy core 126.

FIG. 16C illustrates a perspective view of a portion of the first package component 100 shown in FIG. 16A. A 3D inductor 135 is shown that comprises a conductive trace that forms a coil that is wound around top surfaces, bottom surfaces, outer sidewalls and inner sidewalls of a permalloy core 126. The conductive trace of the 3D inductor 135 comprises portions of the lower RDL 110, the upper RDL 134, and the plurality of conductive vias 120 electrically connected as shown to form an electrically conductive coil that is wound around the permalloy core 126. The integrated circuit die 50 is disposed such that a perimeter of the integrated circuit die 50 is encircled by the closed loop of the permalloy 126. Electrically conducting inductor connections (ports) 152 and 154 provide electrical I/O connection to the 3D inductor 135. The density of coils per unit length of the conductive coil may be selected as desired to provide to provide desired values of inductance.

FIG. 16D illustrates traces of inductance versus operating frequency for different types of inductors. Trace 202 illustrates inductance versus operating frequency for an example 3D inductor 135 comprising a permalloy core 126 as described above. The permalloy core 126 includes the plurality of alternating layers comprising permalloy layers 127 and epoxy layers 125. Trace 204 corresponds to an inductor that includes a solid permalloy core configured as a closed loop, the solid permalloy core being made of single permalloy layer with no epoxy layers. Trace 206 corresponds to an inductor that comprises a permalloy core that is similar to the permalloy core 126. A conductive coil is wound around the permalloy core, with an air-gap being disposed between the conductive coil and the permalloy core. Trace 208 corresponds to an inductor that comprises a conductive coil. Additionally, the inductor has no solid or ferromagnetic material disposed in between the conductive coil (also referred to as an air-core inductor). As illustrated in FIG. 16D, the 3D inductor 135 incorporating the permalloy core 126 has the highest inductance between operating frequencies between 100 KHz and 100 MHz.

FIG. 16E illustrates traces of resistance versus operating frequency for different types of inductors. Trace 210 shows a trace of resistance versus operating frequency for an example 3D inductor 135 comprising the permalloy core 126. The permalloy core 126 includes the plurality of alternating layers comprising permalloy layers 127 and epoxy layers 125. Trace 212 corresponds to an inductor that comprises a solid permalloy core in the form of a closed loop, wherein the permalloy core comprises a single permalloy layer and no epoxy layers. Trace 214 corresponds to an inductor that comprises a permalloy core that is similar to the permalloy core 126. A conductive coil is wound around the permalloy core, with an air-gap being disposed between the conductive coil that is wound around the permalloy core. Trace 216 corresponds to an inductor that comprises a conductive coil. Additionally, the inductor has no solid or ferromagnetic material disposed in between the conductive coil (also referred to as an air-core inductor). As illustrated in FIG. 16E, the 3D inductor 135 incorporating the permalloy core 126 has the highest resistance between operating frequencies between 100 KHz and 100 MHz.

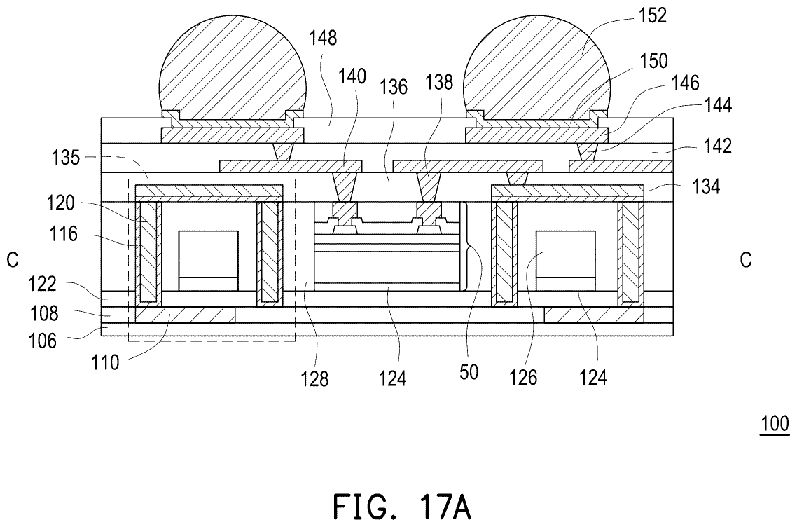

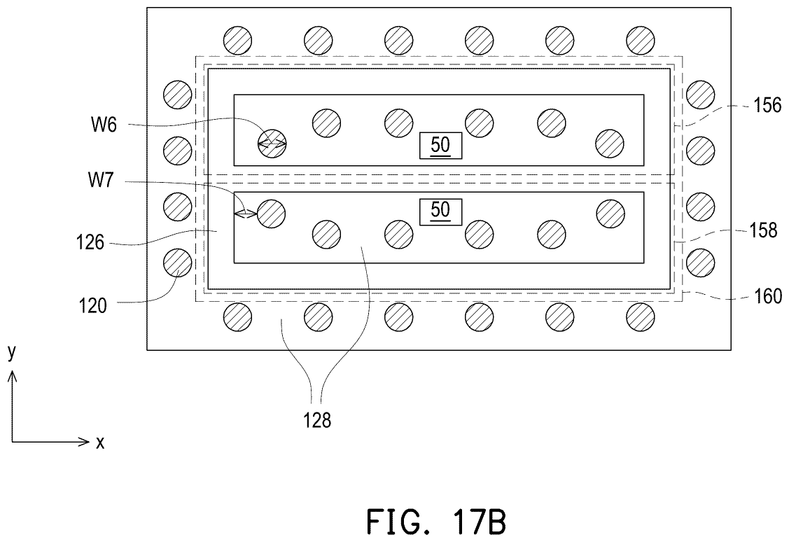

FIGS. 17A and 17B illustrate the first package component 100 in accordance with some other embodiments. Unless specified otherwise, like reference numerals in this embodiment (and subsequently discussed embodiments) represent like components in the embodiment shown in FIGS. 1 through 16E formed by like processes. Accordingly, the process steps and applicable materials may not be repeated herein. FIG. 17A illustrates a cross-sectional view of the first package component 100. FIG. 17B illustrates a top-down view of a cross-section of the first package component 100 along a line C-C shown in FIG. 17A. FIG. 17B is illustrated in a way that identifies a first direction (e.g., the x-direction), and a second direction (e.g., the −y direction), wherein the second direction is orthogonal to the first direction. In FIGS. 17A and 17B, a permalloy core 126 is shown that includes a magnetic bar comprising a plurality of alternating layers that are vertically stacked. The plurality of alternating layers include permalloy layers 127 and epoxy layers 125, such that each permalloy layer 127 is disposed between two epoxy layers 125. The magnetic bar is formed such that it comprises a plurality of closed loops. For example, as illustrated in FIG. 17B, the permalloy core 126 may comprise a first closed loop 156 and a second closed loop 158 that are adjacent to each other in a first direction (e.g., the y-direction). A third closed loop 160 encompasses an entire outer perimeter of the permalloy core 126. In an embodiment, one or more integrated circuit dies 50 may be disposed such that the first closed loop 156 encircles an entire perimeter of the one or more integrated circuit dies 50. In an embodiment, one or more integrated circuit dies 50 may be disposed such that the second closed loop 158 encircles an entire perimeter of the one or more integrated circuit dies 50. In an embodiment, each of the first closed loop 156 and the second closed loop 158 encircles an entire perimeter of at least one integrated circuit die 50. First conductive traces, second conductive traces and third conductive traces comprising portions of the lower RDL 110, the upper RDL 134, and the plurality of conductive vias 120 can be electrically connected to form electrically conductive coils that are wound around the first closed loop 156, the second closed loop 158, and the third closed loop 160, respectively, to form a first 3D inductor 135, a second 3D inductor 135, and a third 3D inductor 135. The density of coils per unit length of the conductive coil may be selected as desired to provide to provide desired values of inductance. Each of the first 3D inductor 135, the second 3D inductor 135, and the third 3D inductor 135 may have an electrically conducting inductor input connection (port) and an electrically conducting inductor output connection (port). In an embodiment, a single inductor input connection (port) and a single inductor output connection (port) may provide electrical I/O connection to the first 3D inductor 135, the second 3D inductor 135, and the third 3D inductor 135.

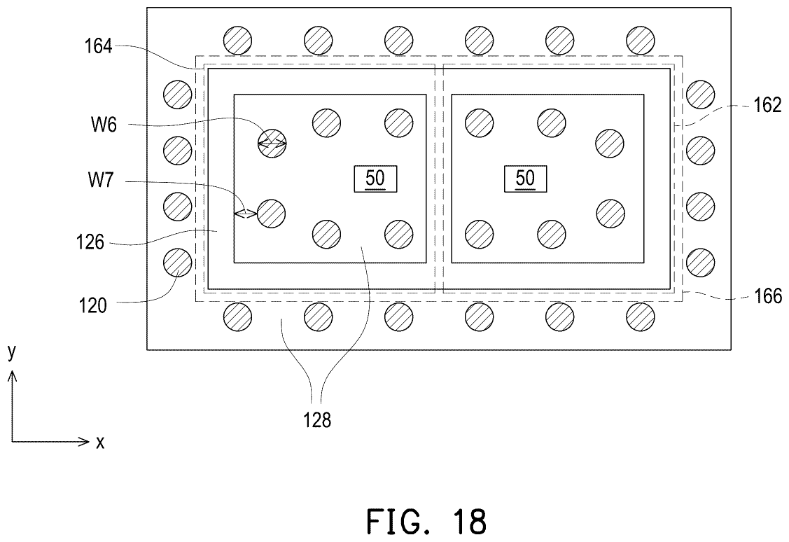

FIG. 18 illustrates the first package component 100 in accordance with some other embodiments. Unless specified otherwise, like reference numerals in this embodiment (and subsequently discussed embodiments) represent like components in the embodiment shown in FIGS. 1 through 16E formed by like processes. Accordingly, the process steps and applicable materials may not be repeated herein. FIG. 18 illustrates a top-down view of a cross-section of the first package component 100 along a line B-B shown in FIG. 16A. FIG. 18 is illustrated in a way that identifies a first direction (e.g., the x-direction), and a second direction (e.g., the −y direction), wherein the second direction is orthogonal to the first direction. In FIG. 18, a permalloy core 126 is shown that includes a magnetic bar comprising a plurality of alternating layers that are vertically stacked. The plurality of alternating layers include permalloy layers 127 and epoxy layers 125, such that each permalloy layer 127 is disposed between two epoxy layers 125. The magnetic bar is formed such that it comprises a plurality of closed loops. For example, as illustrated in FIG. 18, the permalloy core 126 may comprise a first closed loop 162 and a second closed loop 164 that are adjacent to each other in a second direction (e.g., the x-direction). A third closed loop 166 encompasses an entire outer perimeter of the permalloy core 126. In an embodiment, one or more integrated circuit dies 50 may be disposed such that the first closed loop 162 encircles an entire perimeter of the one or more integrated circuit dies 50. In an embodiment, one or more integrated circuit dies 50 may be disposed such that the second closed loop 164 encircles an entire perimeter of the one or more integrated circuit dies 50. In an embodiment, each of the first closed loop 162 and the second closed loop 164 encircles an entire perimeter of at least one integrated circuit die 50. First conductive traces, second conductive traces and third conductive traces comprising portions of the lower RDL 110, the upper RDL 134, and the plurality of conductive vias 120 can be electrically connected to form electrically conductive coils that are wound around the first closed loop 162, the second closed loop 164, and the third closed loop 166, respectively, to form a first 3D inductor 135, a second 3D inductor 135, and a third 3D inductor 135. The density of coils per unit length of the conductive coil may be selected as desired to provide to provide desired values of inductance. Each of the first 3D inductor 135, the second 3D inductor 135, and the third 3D inductor 135 may have an electrically conducting inductor input connection (port) and an electrically conducting inductor output connection (port). In an embodiment, a single inductor input connection (port) and a single inductor output connection (port) may provide electrical I/O connection to the first 3D inductor 135, the second 3D inductor 135, and the third 3D inductor 135.

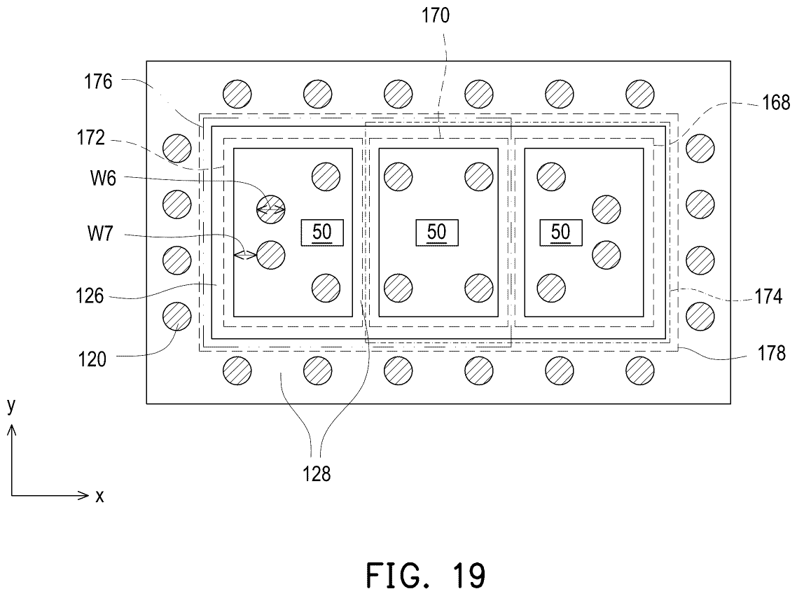

FIG. 19 illustrates the first package component 100 in accordance with some other embodiments. Unless specified otherwise, like reference numerals in this embodiment (and subsequently discussed embodiments) represent like components in the embodiment shown in FIGS. 1 through 16E formed by like processes. Accordingly, the process steps and applicable materials may not be repeated herein. FIG. 19 illustrates a top-down view of a cross-section of the first package component 100 along a line B-B shown in FIG. 16A. FIG. 19 is illustrated in a way that identifies a first direction (e.g., the x-direction), and a second direction (e.g., the −y direction), wherein the second direction is orthogonal to the first direction. In FIG. 19, a permalloy core 126 is shown that includes a magnetic bar comprising a plurality of alternating layers that are vertically stacked. The plurality of alternating layers include permalloy layers 127 and epoxy layers 125, such that each permalloy layer 127 is disposed between two epoxy layers 125. The magnetic bar is formed such that it comprises a plurality of closed loops. For example, as illustrated in FIG. 19, the permalloy core 126 may comprise a first closed loop 168, a second closed loop 170 adjacent to the first closed loop 168 in the second direction (e.g., the x-direction), and a third closed loop 172 adjacent to the second closed loop 170 in the second direction (e.g., the x-direction), such that the second closed loop 170 is disposed between the first closed loop 168 and the third closed loop 172. The permalloy core 126 may also comprise a fourth closed loop 174 that encompasses an outer perimeter of the combination of the first closed loop 168 and the second closed loop 170. In addition, the permalloy core 126 may also comprise a fifth closed loop 176 that encompasses an outer perimeter of the combination of the second closed loop 170 and the third closed loop 172. A sixth closed loop 178 encompasses an entire outer perimeter of the permalloy core 126. In an embodiment, one or more integrated circuit dies 50 may be disposed such that the first closed loop 168 encircles an entire perimeter of the one or more integrated circuit dies 50. In an embodiment, one or more integrated circuit dies 50 may be disposed such that the second closed loop 170 encircles an entire perimeter of the one or more integrated circuit dies 50. In an embodiment, one or more integrated circuit dies 50 may be disposed such that the third closed loop 172 encircles an entire perimeter of the one or more integrated circuit dies 50. In an embodiment, each of the first closed loop 168, the second closed loop 170, and the third closed loop 172 encircles an entire perimeter of at least one integrated circuit die 50. First conductive traces, second conductive traces, third conductive traces, fourth conductive traces, fifth conductive traces and sixth conductive traces comprising portions of the lower RDL 110, the upper RDL 134, and the plurality of conductive vias 120 can be electrically connected to form electrically conductive coils that are wound around the first closed loop 168, the second closed loop 170, the third closed loop 172, the fourth closed loop 174, the fifth closed loop 176 and the sixth closed loop 178 respectively, to form a first 3D inductor 135, a second 3D inductor 135, a third 3D inductor 135, a fourth 3D inductor 135, a fifth 3D inductor 135, and a sixth 3D inductor 135. The density of coils per unit length of the conductive coil may be selected as desired to provide to provide desired values of inductance. Each of the first 3D inductor 135, the second 3D inductor 135, the third 3D inductor 135, the fourth 3D inductor 135, the fifth 3D inductor 135 and the sixth 3D inductor 135 may have an electrically conducting inductor input connection (port) and an electrically conducting inductor output connection (port). In an embodiment, a single inductor input connection (port) and a single inductor output connection (port) may provide electrical I/O connection to the first 3D inductor 135, the second 3D inductor 135, the third 3D inductor 135, the fourth 3D inductor 135, the fifth 3D inductor 135, and the sixth 3D inductor 135.

The embodiments of the present disclosure have some advantageous features. The embodiments include the formation of an integrated circuit package that includes an inductor having a magnetic permalloy core. The permalloy core comprises a plurality of vertically stacked alternating layers that include a plurality of permalloy layers and a plurality of epoxy layers, such that each permalloy layer of the plurality of permalloy layers is disposed between two epoxy layers of the plurality of epoxy layers. The permalloy core may be a magnetic bar that is formed to be in the shape of a closed loop (e.g., having a toroidal loop shape, rectangular loop shape, or the like), or may comprise a plurality of closed loops. As a result, one or more embodiments disclosed herein result in increased magnetic permeability of the permalloy core, which allows for a higher inductance to be achieved. The permalloy core comprising a plurality of closed loops also allows for a further increase in inductance. Further, the disclosed method may provide more efficient and compact power inductors that can be integrated easily into existing processes and provide improved inductor performance with lower manufacturing costs and reduced spacing needs.

In accordance with an embodiment, a package includes a first redistribution structure; a die disposed over the first redistribution structure; a molding material surrounding the die; a second redistribution structure over the die and the molding material; and an inductor including a permalloy core, where the permalloy core is embedded in the molding material, and where the permalloy core includes a plurality of vertically stacked alternating layers, the vertically stacked alternating layers including a plurality of epoxy layers; and a plurality of permalloy layers, where each of the plurality of permalloy layers is disposed between two epoxy layers of the plurality of epoxy layers. In an embodiment, each of the plurality of permalloy layers includes Ni, Fe, Co, Mo, Si, Nb, B, or a combination thereof. In an embodiment, each of the plurality of permalloy layers includes CoFeB. In an embodiment, each of the plurality of permalloy layers has a thickness in a range that is from 1 μm to 50 μm. In an embodiment, each of the plurality of epoxy layers has a thickness in a range that is from 1 μm to 10 μm. In an embodiment, the permalloy core includes a magnetic bar that is in a shape of a closed loop in a top-down view. In an embodiment, the closed loop of the permalloy core encircles an entire perimeter of the die. In an embodiment, the permalloy core includes a magnetic bar that is in a shape that includes a plurality of closed loops in a top-down view.

In accordance with an embodiment, a package includes a first redistribution structure; a molding material over the first redistribution structure; a die embedded in the molding material; a second redistribution structure over the die and the molding material; and an inductor including a first metallization pattern in the first redistribution structure; conductive vias extending through the molding material; a second metallization pattern in the second redistribution structure; and a magnetic bar having a shape of a closed loop in a top-down view, the magnetic bar being embedded in the molding material. In an embodiment, the first metallization pattern, the conductive vias, and the second metallization pattern are electrically connected and form a conductive trace that coils around top surfaces, bottom surfaces and sidewalls of the magnetic bar. In an embodiment, the magnetic bar includes a plurality of vertically stacked alternating layers, the vertically stacked alternating layers including a plurality of epoxy layers; and a plurality of permalloy layers. In an embodiment, a topmost layer and a bottommost layer of the magnetic bar include epoxy layers of the plurality of epoxy layers. In an embodiment, a first dielectric layer is disposed between the magnetic bar and the first redistribution structure, where the conductive vias extend through the first dielectric layer. In an embodiment, the closed loop of the magnetic bar encircles an entire perimeter of the die. In an embodiment, a thickness of the molding material above a top surface of the magnetic bar is at least 10 μm.

In accordance with an embodiment, a method of forming an integrated circuit package including an inductor includes forming a first redistribution structure over a carrier; forming a plurality of conductive vias over the first redistribution structure; attaching a first die over the first redistribution structure; attaching a permalloy core over the first redistribution structure and adjacent to the first die, where the permalloy core includes a magnetic bar having a shape of a closed loop; and forming a second redistribution structure over the first die and the permalloy core. In an embodiment, the method further includes after forming the plurality of conductive vias depositing a first dielectric layer on the first redistribution structure. In an embodiment, the method further includes forming a molding material on the first dielectric layer, where the molding material surrounds the first die and the permalloy core. In an embodiment, the magnetic bar includes a plurality of epoxy layers and a plurality of permalloy layers, and where each of the plurality of permalloy layers is disposed between two epoxy layers of the plurality of epoxy layers. In an embodiment, the plurality of permalloy layers include CoFeB.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming an integrated circuit package including an inductor, the method comprising:
forming a first redistribution structure over a carrier;
forming a plurality of conductive vias over the first redistribution structure;
attaching a first die over the first redistribution structure;
attaching a permalloy core over the first redistribution structure and adjacent to the first die, wherein the permalloy core comprises a magnetic bar having a shape of a closed loop; and
forming a second redistribution structure over the first die and the permalloy core.

2. The method of claim 1, further comprising:
after forming the plurality of conductive vias depositing a first dielectric layer on the first redistribution structure.

3. The method of claim 2, further comprising:
forming a molding material on the first dielectric layer, wherein the molding material surrounds the first die and the permalloy core.

4. The method of claim 1, wherein the magnetic bar comprises a plurality of epoxy layers and a plurality of permalloy layers, and wherein each of the plurality of permalloy layers is disposed between two epoxy layers of the plurality of epoxy layers.

5. The method of claim 4, wherein the plurality of permalloy layers comprise CoFeB.

6. A method of forming an integrated circuit package, the method comprising:
forming a first redistribution structure over a carrier substrate;
attaching a first die over the first redistribution structure;
attaching a magnetic bar over the first redistribution structure, wherein the magnetic bar comprises a closed loop that encircles the entire perimeter of the first die; and
forming a second redistribution structure over the first die and the magnetic bar.

7. The method of claim 6, further comprising:
prior to attaching the first die over the first redistribution structure, forming a plurality of conductive vias over the first redistribution structure.

8. The method of claim 6, further comprising:
forming a molding material over the first redistribution structure, wherein the molding material surrounds the first die and the magnetic bar.

9. The method of claim 8, wherein the molding material is disposed between a top surface of the magnetic bar and the second redistribution structure.

10. The method of claim 6, wherein the magnetic bar comprises a plurality of epoxy layers and a plurality of permalloy layers.

11. The method of claim 10, wherein the plurality of permalloy layers comprises at least eight permalloy layers.

12. The method of claim 10, wherein each permalloy layer of the plurality of permalloy layers comprises CoFeB.

13. The method of claim 10, wherein each permalloy layer of the plurality of permalloy layers comprises an alloy.

14. The method of claim 6, wherein the magnetic bar has a rectangular shape when seen in a top-down view, and wherein outer corners and inner corners of the magnetic bar are rounded.

15. A method of forming an integrated circuit package, the method comprising:
bonding a first die and a magnetic bar to a first redistribution structure, wherein the magnetic bar comprises a closed loop, and wherein the magnetic bar comprises a plurality of epoxy layers and a plurality of permalloy layers;
forming a molding material over the first redistribution structure, wherein the molding material surrounds the first die and the magnetic bar; and
forming a second redistribution structure over the first die, the molding material, and the magnetic bar.

16. The method of claim 15, wherein the plurality of permalloy layers comprises at least eight permalloy layers.

17. The method of claim 16, wherein each permalloy layer of the plurality of permalloy layers comprises CoFeB.

18. The method of claim 15, wherein each permalloy layer of the plurality of permalloy layers has a thickness that is in a range from 1 μm to 50 μm.

19. The method of claim 18, wherein each epoxy layer of the plurality of epoxy layers has a thickness that is in a range from 1 μm to 10 μm.

20. The method of claim 15, wherein the closed loop of the magnetic bar encircles the entire perimeter of the first die.
